(19) United States
(12) Patent Application Publication
(10) Pub. No.: US 2023/0064390 A1
(43) Pub. Date: Mar. 2, 2023

(54) SUBSTRATE TREATING APPARATUS

(71) Applicant: SEMES CO., LTD., Cheonan-Si (KR)

(72) Inventors: Min Sung JEON, Osan-si (KR); Yun Sang KIM, Seongnam-si (KR); Sung Min CHOI, Osan-si (KR); Dong Young JANG, Seongnam-si (KR); Ji Heon KIM, Hwaseong-si (KR); Young Jo JIN, Hwaseong-si (KR)

(73) Assignee: SEMES CO., LTD., Cheonan-si (KR)

(21) Appl. No.: 17/895,540

(22) Filed: Aug. 25, 2022

(30) Foreign Application Priority Data
Aug. 26, 2021 (KR) 10-2021-0113115

(51) Int. Cl. H01J 37/32

(52) U.S. Cl. CPC H01J 37/3255; H01J 37/32541; H01J 37/32724; H01J 37/32495

(57) ABSTRACT

The inventive concept provides a substrate treating apparatus. The substrate treating apparatus includes a chamber having a treating space therein; a support unit positioned within the treating space and configured to support a substrate; and a plasma generation unit configured to generate a plasma from a process gas supplied to the treating space, and wherein the plasma generation unit includes: a bottom electrode member; and a top electrode member opposite the bottom electrode, and wherein the top electrode member includes: a first plate; and an electrode layer on the first plate and including an electrode.

### CROSS-REFERENCE TO RELATED APPLICATIONS

A claim for priority under 35 U.S.C. § 119 is made to Korean Patent Application No. 10-2021-0113115 filed on Aug. 26, 2021, in the Korean Intellectual Property Office, the entire contents of which are hereby incorporated by reference.

### BACKGROUND

Embodiments of the inventive concept described herein relate to a substrate treating apparatus for treating a substrate using a plasma.

In order to manufacture a semiconductor element, a desired pattern is formed on a substrate by performing various processes such as a photolithography process, an etching process, an ashing process, an ion implantation process, a thin film deposition process, and a cleaning process. Among them, the etching process is a process of removing a selected region from a film formed on the substrate, and a wet etching and a dry etching are used.

Among them, an etching device using a plasma is used for the dry etching. Generally, in order to form the plasma, an electromagnetic field is formed in an inner space of a chamber, and the electromagnetic field generates the plasma from a process gas provided in the chamber.

The plasma refers to an ionized gas state made of ions, electrons, or radicals. In a semiconductor element manufacturing process, the etching process is performed using the plasma.

In the substrate treating apparatus using the plasma, a method of increasing a temperature of the substrate increases the temperature of the substrate by using a heating means (heating wire) of a substrate support member on which the substrate is placed. In the case of a method of heating the substrate using a conventional heater, it takes a long time to increase and decrease the temperature, and it is difficult to uniformly heat an entire substrate.

To solve this problem, a method of annealing the substrate using various high-speed heat sources (e.g., infrared lamps, flashes, lasers, microwaves, etc.) at a top of the chamber is presented. By shortening a time required for a heating by using such a method, it is possible to contribute to an improvement of a semiconductor chip productivity.

### SUMMARY

Embodiments of the inventive concept provide a substrate treating apparatus which may perform a plasma treatment and a fast heating in one chamber, and which may improve an etching on a substrate or a uniformity of a film formation.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chamber having a treating space therein; a support unit positioned within the treating space and configured to support a substrate; and a plasma generation unit configured to generate a plasma from a process gas supplied to the treating space, and wherein the plasma generation unit includes: a bottom electrode member; and a top electrode member opposite the bottom electrode, and wherein the top electrode member includes: a first plate; and an electrode layer on the first plate and including an electrode.

In an embodiment, the electrode layer is made of and/or comprises a transparent material.

In an embodiment, the electrode layer includes an ITO, an MnSnO, a CNT, a ZnO, an IZO, an ATO, an SnO₂, IrO₂, RuO₂, a graphene, a carbon nanotube (CNT), an AZO, an FTO, a GZO, an In₂O₃, an MgO, a conductive polymer, a metal nanowire, mixtures thereof, or multiple layers thereof.

In an embodiment, the electrode includes a plurality of ring-shaped concentric electrode segments.

In an embodiment, the plurality of ring-shaped concentric electrode segments have the same spacing and different widths.

In an embodiment, the plurality of ring-shaped concentric electrode segments have the same width and different spacings.

In an embodiment, the electrode includes a plurality of line electrode segments arranged side by side.

In an embodiment, the electrode includes a plurality of first line electrode segments and a plurality of second line electrode segments, the first line electrode segments crossing and connected to the second line electrode segments.

In an embodiment, the electrode includes a plurality of first electrode segments and a plurality of second electrode segments alternatively arranged, one ends of the first electrode segments being connected to each other and opposite ends of the second electrode segments being connected to each other.

In an embodiment, the electrode includes a plurality of rectangular ring segments having the same center and different diameters.

In an embodiment, the electrode includes a first rectangular helix segment and a second rectangular helix segment, the starting end of the first rectangular helix segment connected to the starting end of the second rectangular helix segment.

In an embodiment, the electrode includes a plurality of ring-shaped concentric electrodes, each ring-shaped electrode segment having arc portions spaced part from each other, and respective arc portions of the plurality of ring-shaped concentric electrodes being connected to each other by respective connection portion.

In an embodiment, the bottom electrode member, the top electrode member or both the top and bottom electrode member is connected to a power source.

In an embodiment, one of the bottom electrode member and the top electrode member is applied with the power source, and the other is grounded.

In an embodiment, the first plate is made of and/or comprises a transparent material.

In an embodiment, the first plate is made of and/or comprises a dielectric substance.

In an embodiment, the first plate is made of and/or comprises a quartz material.

In an embodiment, a protective layer of an etching-resistant material is further provided at a surface of the first plate facing the treating space.

In an embodiment, the substrate treating apparatus further includes a heating unit positioned above the top electrode member and irradiating an energy through the top electrode member to the substrate to heat the substrate.

The inventive concept provides a substrate treating apparatus. The substrate treating apparatus includes a chamber having a treating space therein; a support unit positioned within the treating space and configured to support a substrate; a plasma generation unit configured to generate a plasma from a process gas supplied to the treating space and including a bottom electrode member and a top electrode member opposite the bottom electrode member; a power source applying a power to the bottom electrode member, the top electrode member or both the top and bottom electrodes; and a high-speed heating source positioned above the top electrode member and irradiating an energy through the top electrode member to the substrate for heating the substrate, and wherein the top electrode member includes: a first plate made of and/or comprising a quartz material; an electrode layer on the first plate and including a transparent electrode; and a protective layer of an etching-resistant material provided at a side of the first plate facing the treating space.

According to an embodiment of the inventive concept, an etching on a substrate or a uniformity of a film formation may be improved.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a substrate treating apparatus according to an embodiment of the inventive concept.

FIG. 2 is a cross-sectional view illustrating a top electrode member according to an embodiment of the inventive concept.

FIG. 3A to FIG. 4B illustrate a pattern of an electrode layer according to an embodiment of the inventive concept.

FIG. 5A to FIG. 6B illustrate the pattern of the electrode layer according to another embodiment of the inventive concept.

FIG. 7A to FIG. 7I illustrate the pattern of the electrode layer according to another embodiment of the inventive concept.

FIG. 8 is an application example of an embodiment of the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises”, “comprising,”, “includes”, and/or “including” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “example” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Other terms such as “between”, “adjacent”, “near” or the like should be interpreted in the same way.

Unless otherwise defined, all terms used herein, including technical or scientific terms, have the same meaning as those generally understood by those skilled in the art to which the inventive concept belongs. Terms such as those defined in commonly used dictionaries should be interpreted as consistent with the context of the relevant technology and not as ideal or excessively formal unless clearly defined in this application.

In an embodiment of the inventive concept, a substrate treating apparatus for etching a substrate using a plasma will be described. However, the technical characteristics of the inventive concept are not limited thereto, and may be applied to various types of apparatuses that treat the substrate W using the plasma. However, the inventive concept is not limited thereto, and may be applied to various types of apparatuses for plasma-treating a substrate placed on a top.

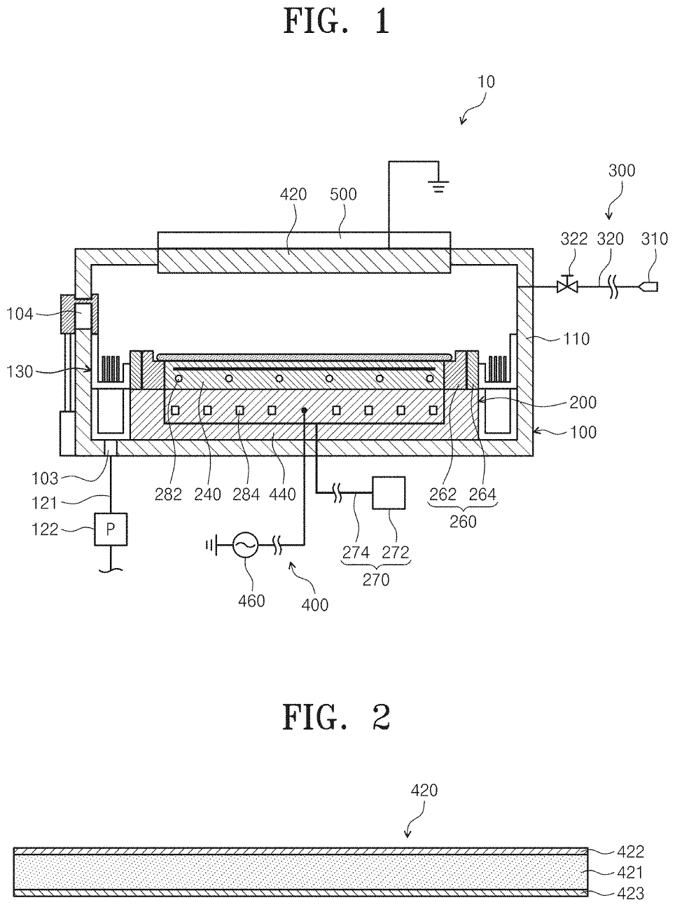

FIG. 1 illustrates a substrate treating apparatus according to an embodiment of the inventive concept.

Referring to FIG. 1, the substrate treating apparatus 10 may include a process chamber 100, a support unit 200, a gas supply unit 300, a plasma generation unit 400, and a heating unit 500. The substrate treating apparatus 10 treats a substrate W using a plasma.

The process chamber 100 has an inner space for performing a process therein. An exhaust hole 103 is formed on a bottom surface of the process chamber 100. The exhaust hole 103 is connected to an exhaust line 121 on which a pump 122 is mounted. The reaction by-products generated during the process and a gas remaining in the process chamber 100 are exhausted to the exhaust hole 103 through the exhaust line 121. Accordingly, they may be discharged to an outside of the process chamber 100. In addition, an inner space of the process chamber 100 is depressurized to a predetermined pressure by an exhaust process. In an embodiment, the exhaust hole 103 may be provided at a position directly connected to a through hole 158 of a liner unit 130 to be described later.

An opening 104 is formed at a sidewall of the process chamber 100. The opening 104 functions as a passage through which the substrate enters and exits the process chamber 100. The opening 104 is opened and closed by a door assembly. According to an embodiment, the door assembly has an outer door, an inner door, and a connection plate. The outer door is provided on an outer wall of the process chamber. The inner door is provided on an inner wall of the process chamber. The outer door and the inner door are fixedly coupled to each other by the connection plate. The connection plate is provided to extend from an inside to an outside of the process chamber through the opening. A door driver moves the outer door in an up/down direction. The door driver may include a pneumatic cylinder or a motor.

The support unit 200 is positioned at a bottom region of the inner space of the process chamber 100. An electrostatic chuck unit may be provided as an embodiment of the support unit 200. The support unit 200 provided as the electrostatic chuck unit supports the substrate W by an electrostatic force. Unlike this, the support unit 200 may support the substrate W in various ways such as a mechanical clamping, a clamping by a vacuum, etc.

The support unit 200 may include an electrostatic chuck 240, a ring assembly 260, and a gas supply line unit 270. The substrate W is placed on a top surface of the electrostatic chuck 240. The electrostatic chuck 240 supports the substrate W on its top surface by an electrostatic force.

The ring assembly 260 is provided in a ring form. The ring assembly 260 is provided to surround a circumference of the support plate 210. In an embodiment, the ring assembly 260 is provided to surround a circumference of the electrostatic chuck 240. The ring assembly 260 supports an edge region of the substrate W. According to an embodiment, the ring assembly 260 has a focus ring 262 and an insulation ring 264. The focus ring 262 is provided to surround the electrostatic chuck 240 and focuses the plasma on the substrate W. The insulation ring 264 is provided to surround the focus ring 262. Selectively, the ring assembly 260 may include an edge ring (not shown) provided in close contact with a circumference of the focus ring 262 to prevent a side surface of the electrostatic chuck 240 from being damaged by the plasma. Unlike the above description, a structure of the ring assembly 260 may be variously changed.

The gas supply line unit 270 includes a gas supply source 272 and a gas supply line 274. The gas supply line 274 is provided between the ring assembly 260 and the support plate 210. The gas supply line 274 supplies a gas to remove foreign substances remaining on a top surface of the ring assembly 260 or an edge region of the support plate 210. In an embodiment, the gas may be a nitrogen gas N₂. Selectively, other gases or cleaning agents may be supplied. The gas supply line 274 may be formed to be connected between the focus ring 262 and the electrostatic chuck 240 in the support plate 210. Unlike this, the gas supply line 274 may be provided inside the focus ring 262 and bent to be connected between the focus ring 262 and the electrostatic chuck 240.

In an embodiment, the electrostatic chuck 240 may be provided as a ceramic material, the focus ring 262 may be provided as a silicone material, and the insulation ring 264 may be provided as a quartz material.

A heating member 282 may be provided inside the electrostatic chuck 240. The heating member 282 may be provided as a hot wire.

A bottom electrode member 440 forming the plasma generation unit 400 may be provided below the electrostatic chuck 240. A cooling means 284 for maintaining the substrate W at a process temperature during a process may be provided in the bottom electrode member 440. The cooling means 284 may be formed inside the bottom electrode member 440 and may be provided as a cooling fluid channel through which a refrigerant flows.

The gas supply unit 300 supplies a process gas to the inner space of the process chamber 100. The gas supply unit 300 includes a gas storage unit 310 and a gas supply line 320. The gas supply line 320 connects the gas storage unit 310 to a gas inlet port of the process chamber 100. The gas supply line 320 supplies the process gas stored at the gas storage unit 310 to the inner space. A valve 322 for opening and closing a passage or for adjusting a flow rate of a fluid flowing through the passage may be installed at the gas supply line 320.

The plasma generation unit 400 generates a plasma from the process gas remaining in a discharge space. The discharge space corresponds to a top region of the support unit 200 in the process chamber 100. The plasma generation unit 400 may have a capacitive coupled plasma source.

The plasma generation unit 400 may include a top electrode member 420, a bottom electrode member 440, and a high frequency power source 460. The top electrode member 420 and the bottom electrode member 440 may be provided opposite each other in the up/down direction. The bottom electrode 440 may be provided in the electrostatic chuck 240.

The plasma generation unit 400 according to an embodiment of the inventive concept may generate the plasma by applying an RF voltage to at least one of the top electrode member 420 and the bottom electrode member 440 in order to generate an electric field between the top electrode member 420 and the bottom electrode member 440.

The top electrode member 420 according to an embodiment of the inventive concept may include a first plate 421 and an electrode layer 422 so that an energy applied from the heating unit 500 to be described below may be transferred to the substrate without loss. The top electrode member 420 according to an embodiment of the inventive concept will be described later in FIG. 2 to FIG. 7.

According to an embodiment, the top electrode member 420 may be grounded, and the high frequency power source 460 may be connected to the bottom electrode member 440. Selectively, the high frequency power source 460 may be connected to the top electrode member 420 and the bottom electrode member 440 may be grounded. In addition, the high frequency power source 460 may be selectively connected to both the top electrode member 420 and the bottom electrode member 440. According to an embodiment, the high frequency power source 460 may continuously apply a power to the top electrode member 420 or the bottom electrode member 440 or apply the power in pulses.

The heating unit 500 may transfer an energy to the substrate to heat the substrate on the support unit 200. The heating unit 500 may be a rapid thermal source. In an embodiment, a high-speed heat source may be provided as a flash lamp generating a flash light, a microwave unit generating a microwave, and a laser unit generating and transmitting a laser. The energy for heating the substrate may be selected as a flash light, a microwave, a laser, or the like.

In an embodiment, when the heating unit 500 is provided as a microwave unit, the heating unit 500 may apply the microwave to the substrate. For example, the heating unit 500 may apply microwaves having a frequency of 1 to 5 GHz. Since a wavelength of the microwave is much longer than a thickness and spacing of a metal wiring layer of a semiconductor chip, a depth at which the microwave penetrates into the metal material is less than several μm. According to an embodiment, a surface of the substrate or a die is heated by a microwave heat treatment, thereby rapidly increasing a surface temperature to a target temperature. When the substrate is heated by the microwave, only the surface of the substrate is selectively heated, and thus a heating speed and a cooling speed are fast, and the surface of the substrate may be heated to the target temperature within a short time, thereby reducing a process time.

Recently, an ALE is applied as an etching process. Atomic layer etching (ALE) is a method of removing a controlled amount of material, using an adsorption reaction that modifies surface of a film and a desorption reaction that removes a modified film surface. Here, the adsorption reaction has a relatively high reactivity at a low temperature (e.g., room temperature), and the desorption reaction has a relatively high reactivity at a high temperature (e.g., 500 degrees Celsius or above). When an embodiment of the inventive concept is applied, a fast heating and a fast cooling are possible, and thus a temperature having a high reactivity in each of the adsorption reaction and desorption reaction may be applied.

According to an embodiment of the inventive concept, the energy such as the flash, the microwave, and the laser may pass through the top electrode member 420 to heat the substrate. The top electrode member 420 may be provided as a light-transmitting and microwave-transmitting material.

FIG. 2 is a cross-sectional view illustrating a top electrode member 420 according to an embodiment of the inventive concept. In the inventive concept, the top electrode member 420 including a transparent electrode 422 is proposed to improve a heat and a plasma uniformity of a substrate. The top electrode member 420 according to the inventive concept may include an electrode layer 422 formed of a pattern and a first plate 421 made of a material different from the electrode layer 422. According to an embodiment, the top electrode member 420 may be provided with an electrode layer 422 on a top surface of the first plate 421. A protective layer 423 made of an etching-resistant material may be provided on a surface of the first plate 421 facing a treating space.

The electrode layer 422 is formed in a pattern as described below. The electrode layer 422 may be grounded or a high frequency power may be connected. The electrode layer 422 may include a transparent electrode. According to an embodiment, the electrode layer 422 may be a transparent electrode formed of an indium tin oxide (ITO) material made of an indium oxide and a tin oxide. In an embodiment, the electrode layer 422 comprises an indium tin oxide (ITO), a manganese tin oxide (MnSnO), a carbon nano tube (CNT), a zinc oxide (ZO), an indium zinc oxide (ITO), an antimony tin oxide (NTO), an SnO₂, an IrO₂, an RuO₂, a dielectric/metal/dielectric multilayer (SnO₂/Ag/SnO₂), a graphene, an FTO (fluorine-doped tin oxide), an AZO (aluminum-doped zinc oxide), a GZO (gallium-doped zinc oxide), an In₂O₃, an MgO, a silver nanowire, a conductive polymer, mixtures thereof, or multiples layers thereof. That is, the electrode layer 422 may be formed of a transparent conductive material. Accordingly, a transmission factor of the energy for a heating described above may be increased. The electrode layer 422 may be disposed at the first plate 421 to be protected from being etched from a plasma.

The protective layer 423 may be provided as an etching-resistant material to prevent an etching of a material during a plasma treatment process.

The first plate 421 may serve as a dielectric window. The first plate 421 may be made of a material having a transparency. According to an embodiment, the first plate 421 may be provided as a quartz material. According to an embodiment, the first plate 421 may be an SiO₂.

According to an embodiment, the electrode layer 422 included in the top electrode member 420, the first plate 421, and the protective layer 423 may be made of and/or comprises a transparent material so that the energy provided from the heating unit 500 passes through. According to an embodiment, the protective layer 423 may be provided as an etching-resistant material. In an embodiment, the protective layer 423 may be any one of an MgAl₂O₄, an Y₂O₃, a YSZ (yttria-stabilized zirconia, ZrO₂/Y₂O₃), a yttrium aluminum garnet (Y₃Al₅O₁₂), an Al₂O₃, a Cr₂O₃, a Nb₂O₅, a γ-AlON, or a SiN₃N₃. Alternatively, it may be provided as a mixture thereof. The protective layer 423 may be made of a material having a transparency, and a plasma resistance and an etching resistance. Accordingly, it may have an excellent conductivity and protect the electrode layer 422.

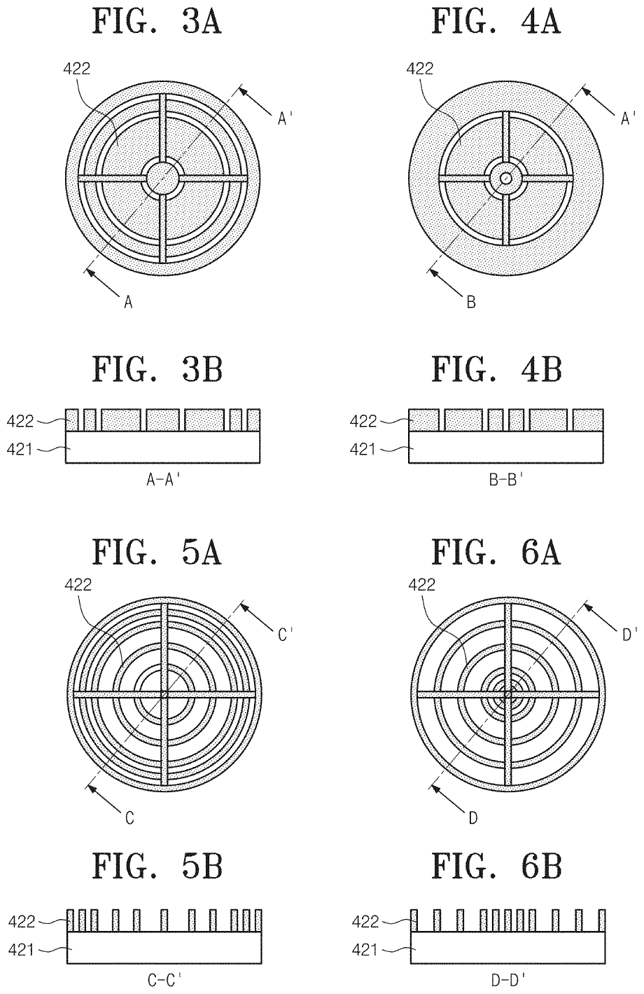

FIG. 3A to FIG. 4B illustrate a pattern of an electrode layer 422 according to an embodiment of the inventive concept. Referring to the two embodiments described in FIG. 3 and FIG. 4, a pattern forming the electrode layer 422 is formed of a combination of a plurality of ring forms with the same center and different diameters. Each of the rings may be connected to each other. The plurality of ring forms forming the electrode layer 422 may have the same spacing and different ring widths. Referring to FIG. 3A and FIG. 3B, for example, a width of a ring formed at an inner region of the electrode layer 422 can be relatively wide, and a width of a ring formed at an outer region can be relatively narrow. For example, referring to FIG. 4A and FIG. 4B, the width of the ring formed at the inner region of the electrode layer 422 may be relatively narrow, a width of the ring formed at a middle region may be relatively wide, and the width of the ring formed at the outer region may be narrower than the middle region. As described above, a plasma density may be adjusted by adjusting a width of the pattern.

FIG. 5A to FIG. 6B illustrate a pattern of an electrode layer 422 according to another embodiment of the inventive concept. Referring to the two embodiments described in FIGS. 5 and 6, a pattern forming the electrode layer 422 is formed of a combination of a plurality of ring forms having the same center and different diameters. Each of the rings may be connected to each other. The plurality of ring forms forming the electrode layer 422 may have the same width of the ring forms and may have different spacings between the ring forms. For example, referring to FIG. 5A and FIG. 5B, a space between the ring forms formed at an inner region of the electrode layer 422 may be relatively wide and a space between the ring forms formed at an outer region may be relatively narrow. For example, referring to FIG. 6A and FIG. 6B, a space between the ring forms formed at the inner region of the electrode layer 422 may be relatively narrow, and a space between the ring forms formed at the outer region may be relatively wide. As described above, a plasma density may be adjusted by adjusting a spacing of the patterns.

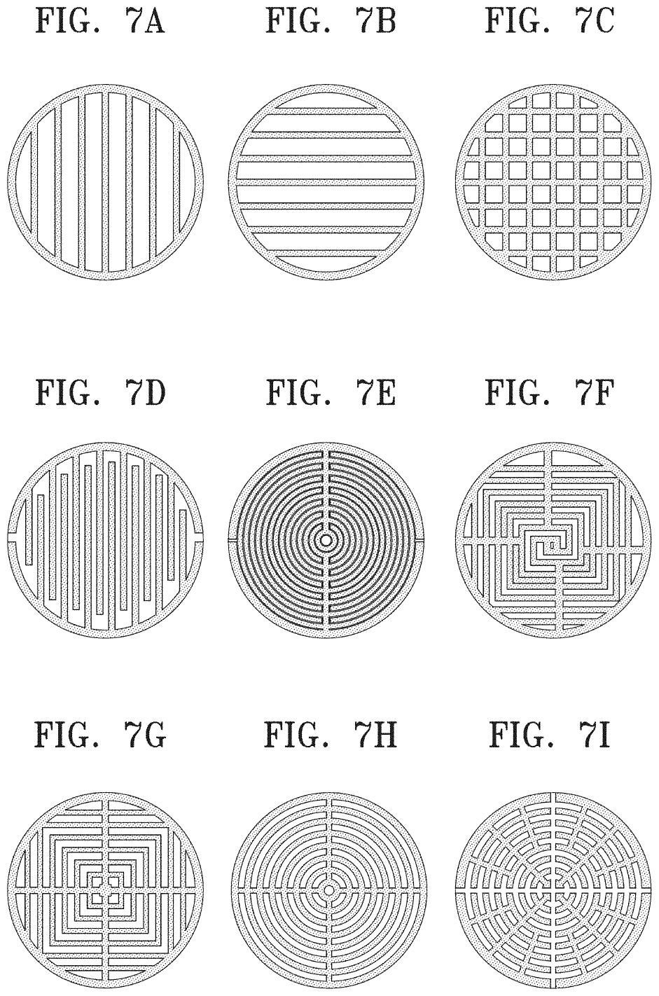

FIG. 7A to FIG. 7I illustrate a pattern of an electrode layer 422 according to another embodiment of the inventive concept. Referring to FIG. 7A and FIG. 7B, a pattern forming the electrode layer 422 is formed by a plurality of line electrode segments arranged side by side. Referring to FIG. 7C, the pattern forming the electrode layer 422 are disposed orthogonal to each other. Referring to FIG. 7D and FIG. 7E, the pattern forming the electrode layer 422 are formed by disposing a first electrode pattern and a second electrode pattern to not meet each other. Referring to FIG. 7F, the pattern forming the electrode layer 422 is formed in a plurality of square forms as a whole. Referring to FIG. 7G, the pattern forming the electrode layer 422 is formed of a combination of the plurality of square forms having the same center and different diameters. Referring to FIG. 7H, the pattern forming the electrode layer 422 is formed of a combination of a plurality of ring forms having the same center and different diameters. Referring to FIG. 7I, as a whole, a combination of a plurality of arc forms forming a plurality of ring forms and a plurality of connection lines connecting the plurality of arcs are included. The pattern may be divided into a plurality of pieces and provided. For example, it can be divided into four pieces.

In addition to the above-described embodiments, various types of electrode patterns in consideration of a plasma density may be applied.

That is, according to the inventive concept, the electrode layer 422 may be formed to have a pattern, and thus the plasma density for each region may be adjusted. For example, a degree of plasma generation for each region may vary according to a structure of an equipment, and the plasma density for each region may be adjusted based on a pattern form of the electrode layer 422 to generate a uniform plasma. By controlling a generation of plasma, it is possible to improve a uniformity of an etching or a film formation on the substrate. Through this, it is possible to increase a productivity of a semiconductor chip.

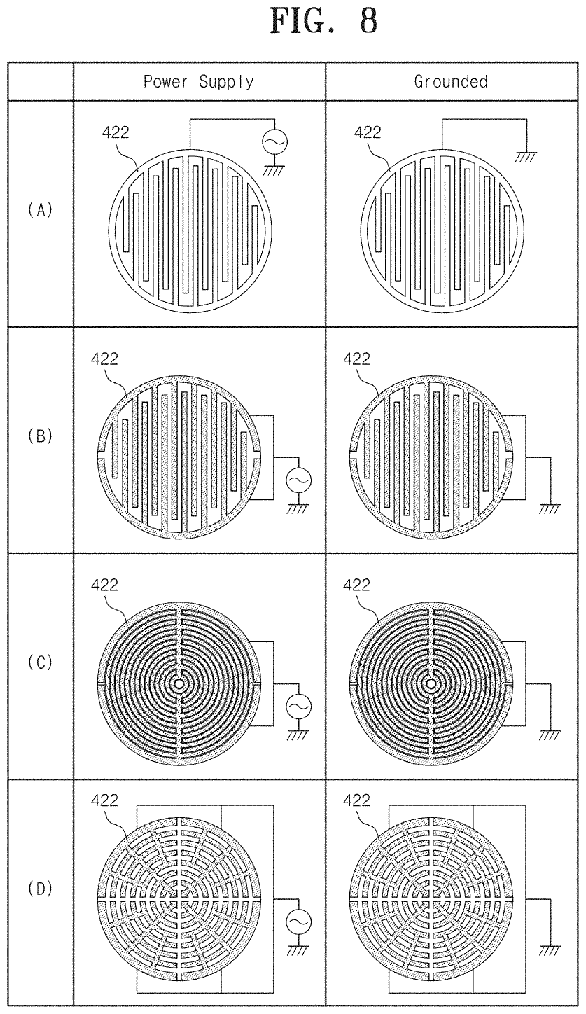

FIG. 8 is an application example of embodiments of the inventive concept. An RF power may be applied to electrode layer 422 or grounded. If grounded, the RF power may be applied to a bottom electrode member 440. As is referred to through (B), (C), and (D), if an electrode pattern is divided, the RF power may be applied to each pattern.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a chamber having a treating space therein;
a support unit positioned within the treating space and configured to support a substrate; and
a plasma generation unit configured to generate a plasma from a process gas supplied to the treating space, and
wherein the plasma generation unit comprises:
a bottom electrode member; and
a top electrode member opposite the bottom electrode, and
wherein the top electrode member comprises:
a first plate; and
an electrode layer on the first plate and including an electrode.

2. The substrate treating apparatus of claim 1, wherein the electrode layer is made of and/or comprises a transparent material.

3. The substrate treating apparatus of claim 1, wherein the electrode layer comprises an ITO, an MnSnO, a CNT, a ZnO, an IZO, an ATO, an SnO₂, IrO₂, RuO₂, a graphene, a carbon nanotube (CNT), an AZO, an FTO, a GZO, an In₂O₃, an MgO, a conductive polymer, a metal nanowire, mixtures thereof, or multiple layers thereof.

4. The substrate treating apparatus of claim 1, wherein the electrode comprises a plurality of ring-shaped concentric electrode segments.

5. The substrate treating apparatus of claim 4, wherein the plurality of ring-shaped concentric electrode segments have the same spacing and different widths.

6. The substrate treating apparatus of claim 4, wherein the plurality of ring-shaped concentric electrode segments have the same width and different spacings.

7. The substrate treating apparatus of claim 1, wherein the electrode comprises a plurality of line electrode segments arranged side by side.

8. The substrate treating apparatus of claim 1, wherein the electrode comprises a plurality of first line electrode segments and a plurality of second line electrode segments, the first line electrode segments crossing and connected to the second line electrode segments.

9. The substrate treating apparatus of claim 1, wherein the electrode comprises a plurality of first electrode segments and a plurality of second electrode segments alternatively arranged, one ends of the first electrode segments being connected to each other and opposite ends of the second electrode segments being connected to each other.

10. The substrate treating apparatus of claim 1, wherein the electrode comprises a plurality of rectangular ring segments having the same center and different diameters.

11. The substrate treating apparatus of claim 1, wherein the electrode comprises a first rectangular helix segment and a second rectangular helix segment, the starting end of the first rectangular helix segment connected to the starting end of the second rectangular helix segment.

12. The substrate treating apparatus of claim 1, wherein the electrode comprises a plurality of ring-shaped concentric electrodes, each ring-shaped electrode segment having arc portions spaced part from each other, and respective arc portions of the plurality of ring-shaped concentric electrodes being connected to each other by respective connection portion.

13. The substrate treating apparatus of claim 1, wherein the bottom electrode member, the top electrode member or both the top and bottom electrode member is connected to a power source.

14. The substrate treating apparatus of claim 1, wherein one of the bottom electrode member and the top electrode member is applied with the power source, and the other is grounded.

15. The substrate treating apparatus of claim 1, wherein the first plate is made of and/or comprises a transparent material.

16. The substrate treating apparatus of claim 1, wherein the first plate is made of and/or comprises a dielectric substance.

17. The substrate treating apparatus of claim 1, wherein the first plate is made of and/or comprises a quartz material.

18. The substrate treating apparatus of claim 1, wherein a protective layer of an etching-resistant material is further provided at a surface of the first plate facing the treating space.

19. The substrate treating apparatus of claim 1 further comprising a heating unit positioned above the top electrode member and irradiating an energy through the top electrode member to the substrate to heat the substrate.

20. A substrate treating apparatus comprising:
a chamber having a treating space therein;
a support unit positioned within the treating space and configured to support a substrate;
a plasma generation unit configured to generate a plasma from a process gas supplied to the treating space and including a bottom electrode member and a top electrode member opposite the bottom electrode member;
a power source applying a power to the bottom electrode member, the top electrode member or both the top and bottom electrodes; and
a high-speed heating source positioned above the top electrode member and irradiating an energy through the top electrode member to the substrate for heating the substrate, and
wherein the top electrode member comprises:
a first plate made of and/or comprising a quartz material;
an electrode layer on the first plate and including a transparent electrode; and
a protective layer of an etching-resistant material provided at a side of the first plate facing the treating space.
